(19) United States
(12) Patent Application Publication
(10) Pub. No.: US 2016/0172036 A1
(43) Pub. Date: Jun. 16, 2016

(54) MEMORY CELL WITH RETENTION USING RESISTIVE MEMORY

(71) Applicants: Charles AUGUSTINE, West Lafayette, IN (US); Carlos TOKUNAGA, Hillsboro, OR (US); James W. TSCHANZ, Portland, OR (US)

(72) Inventors: Charles AUGUSTINE, West Lafayette, IN (US); Carlos TOKUNAGA, Hillsboro, OR (US); James W. TSCHANZ, Portland, OR (US)

(21) Appl. No.: 14/129,676

(22) PCT Filed: Aug. 16, 2013
(86) PCT No.: PCT/US2013/055332

§ 371 Date: Dec. 27, 2013

(51) Int. Cl. G11C 14/00; G11C 11/16

(52) U.S. Cl. CPC G11C 14/0081; G11C 11/1697

(57) ABSTRACT

Described is an apparatus including memory cell with retention using resistive memory. The apparatus comprises: a memory element including cross-coupled cells having a first node and a second node; a first transistor coupled to the first node; a second transistor coupled to the second node; and a resistive memory element coupled to the first and second transistors.

### CLAIM OF PRIORITY

This application claims the benefit of priority of International Patent Application No. PCT/US2013/055332 filed Aug. 16, 2013, titled “MEMORY CELL WITH RETENTION USING RESISTIVE MEMORY,” which is incorporated by reference in its entirety.

### BACKGROUND

Processors and SoCs (System-on-Chip) are power constrained and employ power gating to “turn off” blocks (i.e., to enter sleep state for logic blocks) which are not in use, saving leakage power. Traditionally, switching a block into sleep state requires time in order to save any data which must be retained for correct operation. This data may be stored in embedded memory arrays, flip-flops, and latches and takes time to save into “always on” storage, as well as time to restore the stored data when power is again applied to the block. This data save and restore time limits how frequently the block can be power gated, and also incurs a power penalty which reduces the overall gains.

The standard method for saving and restoring data (i.e., context) involves moving the data into a memory array which is always powered up. Alternatively, state retention flip-flops have been used to locally save the required data in the flip-flops themselves, by isolating a portion of the flip-flop and connecting it to an always-on supply. These flip-flops allow fast context save and restore since the state (i.e., data) does not need to be moved into a memory array. However, such flip-flops require an always-on supply to be routed to every state retention flip-flop, and a portion of the flip-flop consumes leakage power even during sleep mode.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 is a traditional retention flip-flop with two MTJs (magnetic tunnel junctions).

FIG. 2A is a memory cell with retention using a single resistive element and a static restore scheme, according to one embodiment of the disclosure.

FIG. 2B is a plot showing timing waveforms during the restore operation of the static restore scheme of FIG. 2A, according to one embodiment of the disclosure.

FIG. 3 is a memory cell with retention using a single resistive element and a static restore scheme, according to another embodiment of the disclosure.

FIG. 4 is a memory cell with retention using a single resistive element and a static restore scheme, according to another embodiment of the disclosure.

FIG. 5A is a memory cell with retention using a single resistive element and a dynamic restore scheme, according to another embodiment of the disclosure.

FIG. 5B is a plot showing timing waveforms during the restore operation of the dynamic restore scheme of FIG. 5A, according to one embodiment of the disclosure.

FIG. 6 is a memory cell with retention using a single resistive element and a dynamic read restore scheme, according to another embodiment of the disclosure.

FIG. 7 is a memory cell with retention using a single resistive element and a dynamic restore scheme, according to another embodiment of the disclosure.

FIG. 8 is a smart device or a computer system or an SoC (system-on-chip) with the memory cell with retention using a single resistive element, according to one embodiment of the disclosure.

### DETAILED DESCRIPTION

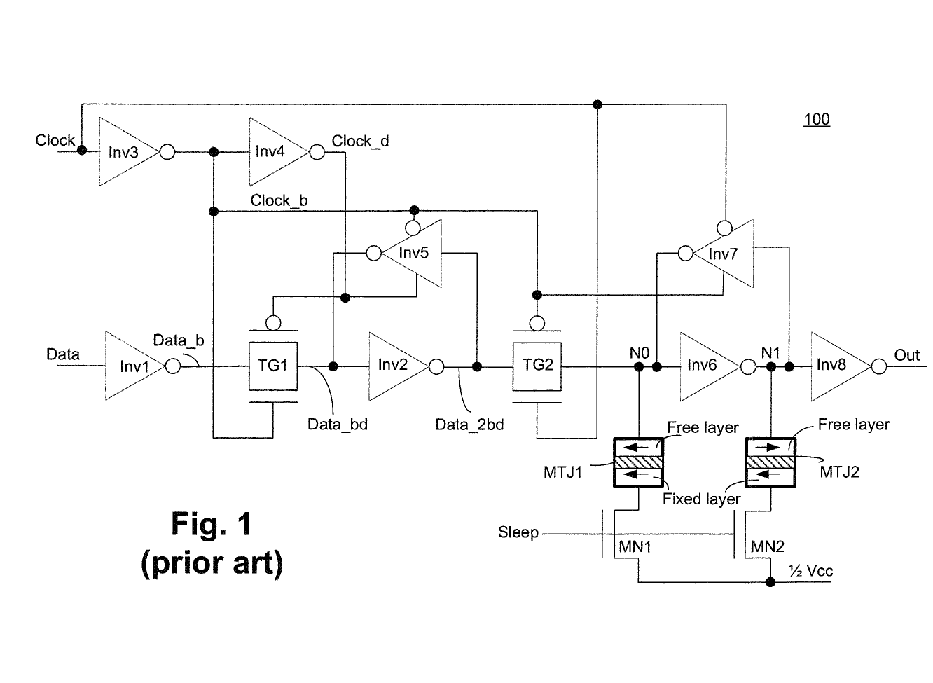

FIG. 1 is a traditional retention flip-flop 100 with two MTJs (magnetic tunnel junctions). Flip-flop 100 consists of a master stage having inverters (inv) Inv1, Inv2, Inv3, Inv4, and Inv5, and transmission gate 1 (TG1); a slave stage having Inv6, Inv7, and Inv8, and TG2; and retention stage having two MTJs-MTJ1 and MTJ2, and sleep transistors MN1 and MN2, coupled together as shown.

Inv1 receives input Data signal on node Data and generates an inverted version of Data signal on node Data_b. The term node and signal on the node may be interchangeably used. For example, node Data and signal Data, which is on node Data, may be referred simply as Data. TG1 is coupled between nodes Data_b and Data_bd. TG1 receives signal Data_b and provides signal Data_b as signal Data_bd on node Data_bd when TG1 is enabled. TG1 is enabled when signal Clock_b is logical high and signal Clock_d is logical low.

Signal Data_bd is received by Inv2 which generates an inverted version of signal Data_bd i.e., signal Data_2bd on node Data_2bd. Inv3 and Inv4 are in the clock path. Inv3 receives signal Clock and generates an inverted version of signal Clock as signal Clock_b on node Clock_b. Inv4 receives signal Clock_b on node Clock b and generates an inverted version of signal Clock_b as signal Clock_d on node Clock_d. Inv5 is used to save data in the master stage. Inv5 is coupled to nodes Data_2bd and Data_b. Inv5 is clock gated i.e., it inverts its input when it is enabled by Clock_b and Clock_d signals.

Output of Inv2 is received by TG2, which when enabled provides signal Data_2bd to node N0. Inv6 and Inv7 are cross-coupled inverters and form a memory element of the slave stage. Inv7 is clock gated like Inv5. Output of Inv6 is node N1 which is coupled to Inv8. Inv8 generates the final output Out. Source/Drain terminals of sleep transistors MN1 and MN2 are tied to always-on half supply (½ Vcc) to retain data at nodes N0 and N1. MN1 and MN2 are controlled by signal Sleep, which when enabled, couple MTJ1 and MTJ2 devices to the half supply rail, respectively.

MTJ device is a non-volatile resistive memory device formed by a stack of layers including an insulation layer formed from MgO, a free layer (i.e., free magnetic layer), and a fixed layer (i.e., fixed magnetic layer or pinned layer). The pattern region of the MTJ is the insulation layer. When current flows through an MTJ device, the direction of current changes the resistivity of the MTJ device such that one direction of current results in high resistivity (RH) while another direction of current through the MTJ results in low resistivity (RL) of the MTJ device.

Sleep state in a processor is used for decreasing overall power dissipation. Retention flip-flops (like flip-flop 100) reduce timing overhead of going into and coming out of sleep states significantly, which can enable new power saving states in processors. However, flip-flop 100 suffers from higher write energy, slower entry and exit from sleep mode, and higher retention failure probability.

Flip-flop 100 isolates the slave stage of the flip-flop during sleep mode (i.e., when signal Sleep is logical high) and maintains the logic state on nodes N1 and NO with an always-on half power supply. The two MTJ devices store complementary data. Complementary data is stored (when entering sleep mode) with the help of half Vcc power supply. The complementary data must be correct otherwise the nodes N0 and N1 of the slave stage may not have the proper last saved states. Free layers of MTJ1 and MTJ2 devices are coupled to nodes N0 and N1, while fixed layer of MTJ1 and MTJ2 devices are coupled to drain/source terminals of MN1 and MN2, respectively. During read-operation (when exiting sleep mode), the difference in current between the two MTJ device branches (i.e., complementary branches) is used to restore values in the complimentary nodes N0 and N1.

When Sleep is activated (i.e., when signal Sleep is logical high), MTJ1 device on the left is programmed to the parallel state and MTJ2 device on the right is programmed to the anti-parallel state, when data stored in the slave stage is ‘1.’ When data stored in the slave stage is ‘0,’ MTJ1 device in the left is in anti-parallel stage and MTJ2 device on the right is in parallel stage. The necessity of routing a separate power supply to all sequential makes this solution difficult to implement. In addition, the retention flip-flop 100 still consumes leakage current in sleep mode. Moreover, using two MTJ devices increases overall area of flip-flop 100.

The embodiments describe an apparatus (i.e., a memory cell) that uses a single resistive device which allows the retention memory cell to save state with no leakage power, and without requiring an always-on supply voltage. Compared to the two-MTJ design of FIG. 1, the embodiments use a single resistive device which can reduce thermal stability of the resistive device, remove the requirement of half-Vcc supply rail (i.e., no half-Vcc supply generator is needed), and results in faster entry into the sleep mode, all of which can save power dissipation.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct electrical connection between the things that are connected, without any intermediary devices. The term “coupled” means either a direct electrical connection between the things that are connected or an indirect connection through one or more passive or active intermediary devices. The term “circuit” means one or more passive and/or active components that are arranged to cooperate with one another to provide a desired function. The term “signal” means at least one current signal, voltage signal or data/clock signal. The meaning of “a,” “an,” and the include plural references. The meaning of “in” includes “in” and “on.”

The term “scaling” generally refers to converting a design (schematic and layout) from one process technology to another process technology. The term “scaling” generally also refers to downsizing layout and devices within the same technology node. The term “scaling” may also refer to adjusting (e.g., slow down) of a signal frequency relative to another parameter, for example, power supply level. The terms “substantially,” “close,” “approximately,” “near,” and “about,” generally refer to being within +/−20% of a target value.

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For purposes of the embodiments, the transistors are metal oxide semiconductor (MOS) transistors, which include drain, source, gate, and bulk terminals. The transistors also include Tri-Gate and FinFet transistors, Gate All Around Cylindrical Transistors or other devices implementing transistor functionality like carbon nano tubes or spintronic devices. Source and drain terminals may be identical terminals and are interchangeably used herein. Those skilled in the art will appreciate that other transistors, for example, Bi-polar junction transistors—BJT PNP/NPN, BiCMOS, CMOS, eFET, etc., may be used without departing from the scope of the disclosure. The term “MN” indicates an n-type transistor (e.g., NMOS, NPN BJT, etc.) and the term “MP” indicates a p-type transistor (e.g., PMOS, PNP BJT, etc.).

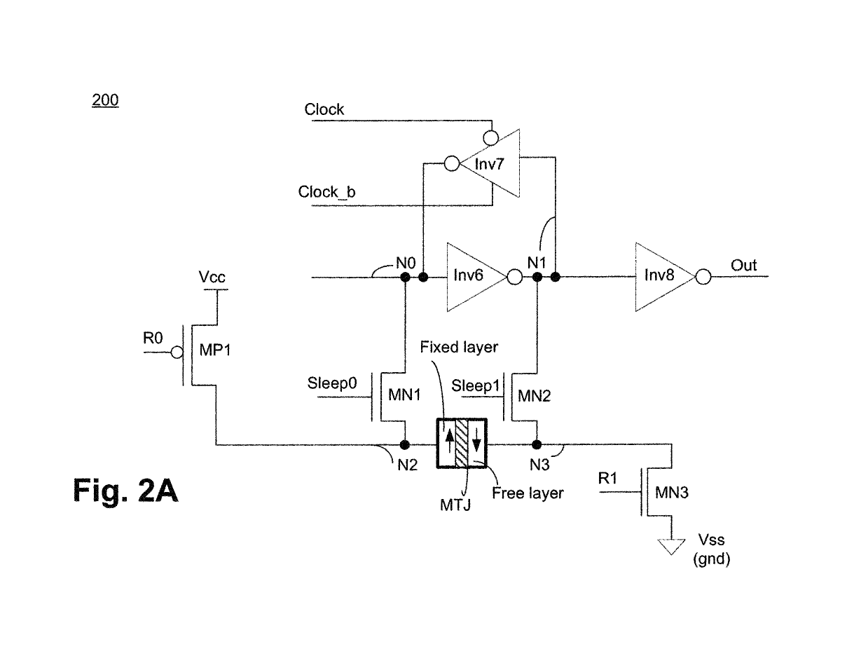

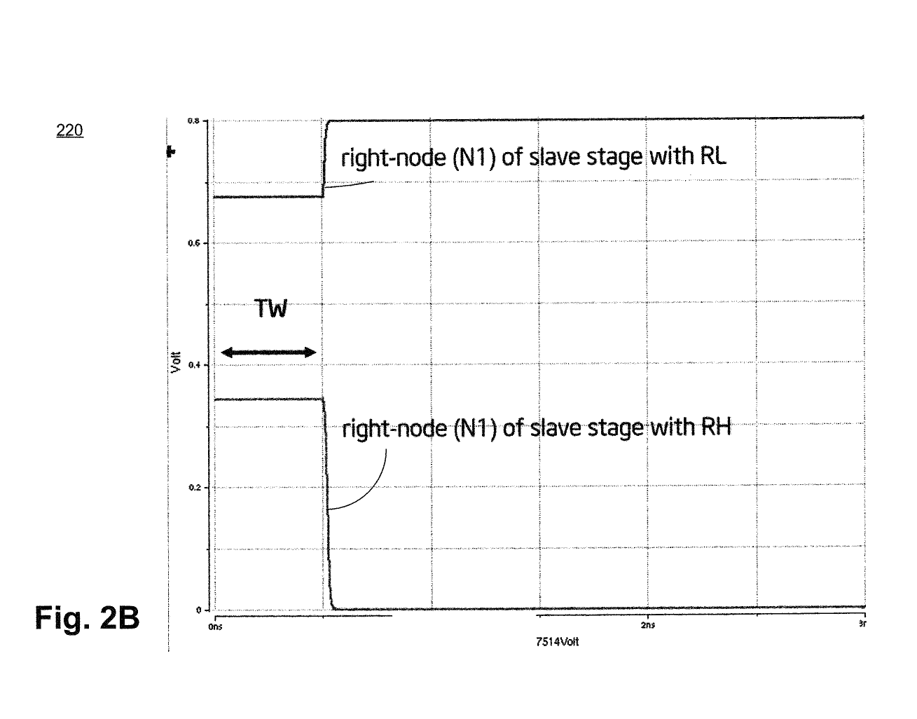

FIG. 2A is a memory cell 200 with retention using a single resistive element and a static restore scheme, according to one embodiment of the disclosure. It is pointed out that those elements of FIG. 2A having the same reference numbers (or names) as the elements of any other figure can operate or function in any manner similar to that described, but are not limited to such. The following embodiments are explained with reference to FIG. 1. So as not to obscure the embodiments, only the slave stage of a flip-flop is shown. The rest of the flip-flop may be similar to flip-flop 100. The embodiments are applicable to any memory element, and are not limited to flip-flops.

In one embodiment, memory cell 200 comprises cross-coupled inverters Inv6 and Inv7, where Inv7 is clock gated. In one embodiment, memory cell 200 further comprises a resistive device coupled to sleep transistors MN1 and MN2. The following embodiments are explained with reference to resistive device being an MTJ device. In other embodiments, the resistive memory element is one of conductive bridge RAM (CBRAM), bi-stable organic memories, or any resistive memory with bi-directional write.

In one embodiment, the restore apparatus of memory cell 200 comprises p-type transistor MP1 and an n-type transistor MN3. In one embodiment, source terminal of MP1 is coupled to Vcc, drain terminal of MP1 is coupled to source/drain terminal of MN1 and fixed layer of MTJ device, and gate terminal is controlled by signal R0. In one embodiment, drain terminal of MN3 is coupled to source/drain terminal of MN2 and free layer of MTJ device, source terminal of MN2 is coupled to ground (Vss), and gate terminal of MN2 is controlled by signal R1. The restore apparatus of memory cell 200 is also referred to as static restore scheme.

In one embodiment, a single MTJ device is used for retaining states of nodes N0 and N1 after sleep mode is over. In one embodiment, drain/source terminal of MN1 (also called first transistor) is coupled to node N0 while the source/drain terminal of MN1 is coupled to one end of the MTJ device (i.e., the fixed layer). MN1 is controlled by signal Sleep0 which is received at the gate terminal of MN1. In one embodiment, drain/source terminal of MN2 (also called second transistor) is coupled to node N1 while the source/drain terminal of MN2 is coupled to the other end of the MTJ device (i.e., the free layer). MN2 is controlled by signal Sleep1 which is received at its gate terminal. Sleep0 and Sleep1 may be tied to the same node i.e., both MN1 and MN2 are controlled by the same sleep signal. For example, during write operation, Sleep0 and Sleep1 are connected together for both MN1 and MN2. In one embodiment, during read/restore operation, Sleep0 and Sleep1 are independently controlled.

During normal mode of operation, signals Sleep0 and Sleep1 are logical low and the memory cell 200 having back-to-back (or cross-coupled) inverters Inv6 and Inv7 operate normally. Memory cell 200 can be a stand-alone memory cell or part of any memory unit. For example, memory cell 200 may be part of a slave stage of a flip-flop, a latch, etc. In the context of a flip-flop, during normal mode of operation, memory cell 200 operates as a regular slave stage of a flip-flop without retention feature. In such an embodiment, performance of the flip-flop is like performance of any regular flip-flop. During sleep mode, i.e., when signals Sleep0 and Sleep1 are logical high, slave stage feedback with retention feature is enabled. In such an embodiment, data is stored in the MTJ device (i.e., data on nodes N0 and N1 are preserved), and the flip-flop or circuit of which memory cell 200 is part of can be completely turned off to reduce power consumption.

Compared to the slave stage of retention flip-flop of FIG. 1, memory cell 200 has a single MTJ device for non-volatile storage. Memory cell 200 also exhibits lower write-failures compared to slave stage of retention flip-flop of FIG. 1 because higher write voltage is applied across the MTJ device. For memory cell 200, half-Vcc power supply is not needed during write operation.

During restore mode (i.e., when Sleep mode is deactivated), data is transferred from the MTJ device (resistance difference) into logical ‘1’ and ‘0’ in the slave stage nodes N0 and N1. In one embodiment, during restore mode (i.e., static restore scheme), R0 is coupled to Vss (ground) and R1 is coupled to Vcc for a shorter time-window (TW). During this time, signal Sleep0 is activated and due to resistive divider action, output of Inv8 goes to Vcc or Vss depending on the resistive state of the MTJ device. In such an embodiment, during restore operation, MP1 and MN3 are turned on. In one embodiment, during the restore operation, the feedback inverter Inv7 of the slave stage is turned off (i.e., clock gated). In one embodiment, when restore mode is over, MP1 is turned off by coupling R0 to Vcc and MN3 is turned off by coupling R1 to Vss.

FIG. 2B is a plot 220 showing timing waveforms during the restore operation of static restore scheme of FIG. 2A, according to one embodiment of the disclosure. It is pointed out that those elements of FIG. 2B having the same reference numbers (or names) as the elements of any other figure can operate or function in any manner similar to that described, but are not limited to such.

The x-axis of plot 220 is time and the y-axis is voltage. Plot 220 shows two waveforms, one on the top and one on the bottom. The top waveform is the voltage on node N1 when resistivity of MTJ device is low (i.e., first state of MJT device, also referred to as RL) while the bottom waveform is the voltage on node N1 when resistivity of MTJ is high (i.e., second state of MTJ device also referred to as RH). TW is the time window during restore operation when R1 is coupled to Vcc and R0 is coupled to Vss. During restore operation (i.e., during the TW time window), signals Sleep0 and Sleep1 are logical high (i.e., MN1 and MN2 are enabled to be turned on). After the TW window, R1 is coupled to Vss and R0 is coupled to Vcc causing nodes N1 and NO to have their restored data states according to resistivity of MTJ device.

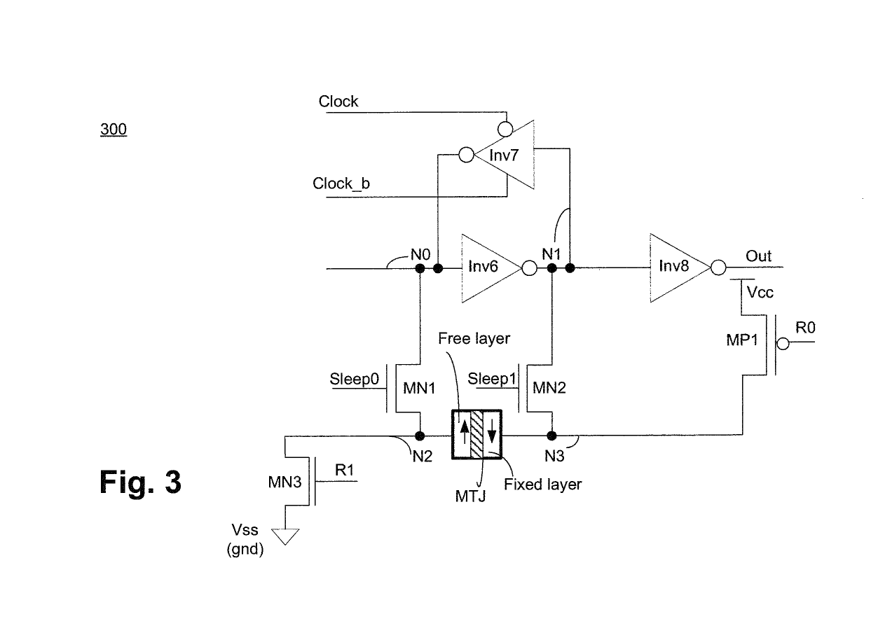

FIG. 3 a memory cell 300 with retention and using single resistive element and a static restore scheme, according to another embodiment of the disclosure. It is pointed out that those elements of FIG. 3 having the same reference numbers (or names) as the elements of any other figure can operate or function in any manner similar to that described, but are not limited to such.

The embodiment of FIG. 3 is similar to the embodiment of FIG. 2A except that MP1 is now coupled to node N3 and source/drain terminal of MN2 while MN3 is coupled to node N2 and source/drain terminal of MN1. The operation of memory cell 300 is similar to the operation of memory cell 200. In this embodiment, MTJ device is flipped i.e., free layer is now coupled to node N2 and fixed layer is now coupled to node N3. In one embodiment, to write into node N0, Sleep0 is coupled to Vcc and Sleep1 is coupled to Vss (to float node N1).

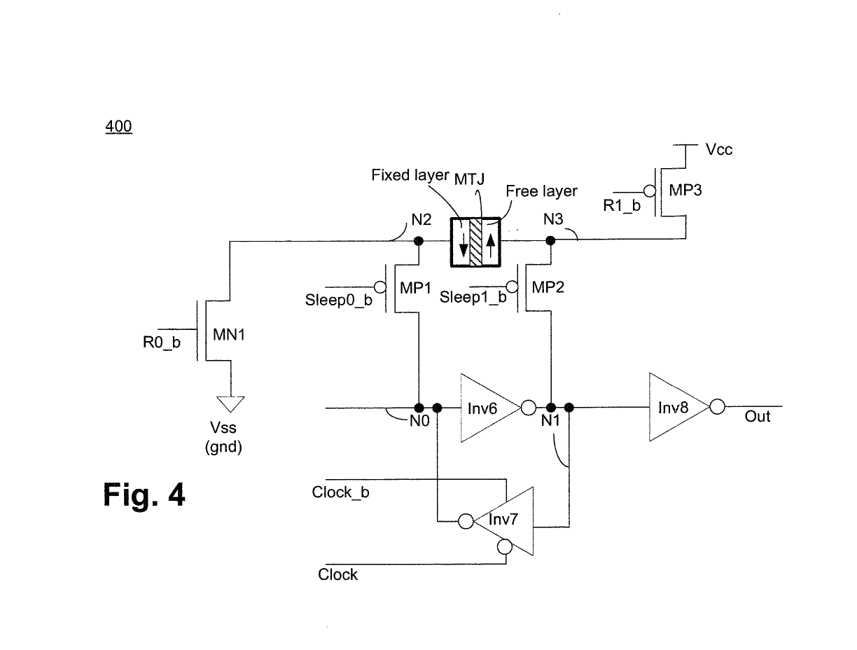

FIG. 4 is a memory cell 400 with retention and using single resistive element and a static restore scheme, according to another embodiment of the disclosure. It is pointed out that those elements of FIG. 4 having the same reference numbers (or names) as the elements of any other figure can operate or function in any manner similar to that described, but are not limited to such.

The embodiment of FIG. 4 is a complementary embodiment of FIG. 2A and functions similarly to FIG. 2A. Memory cell 400 uses p-type sleep transistors MP1 and MP2 instead of n-type sleep transistors MN1 and MN2 of FIG. 2A. In this embodiment, MP1 and MP2 are controlled by signals Sleep0_b and Sleep1_b, where signal Sleep0_b is inverse of signal Sleep0 (of FIG. 2A) and signal Sleep1_b is inverse of signal Sleep1 (of FIG. 2A). In one embodiment, Sleep0_b and Sleep1_b are tied to the same nodes. For example, during write operation, Sleep0_b and Sleep1_b are connected together for both MP1 and MP2. In one embodiment, during read/restore operation, Sleep0 and Sleep1 are independently controlled. In one embodiment, the static retention scheme of FIG. 4 comprises MN1 with its source terminal coupled to Vss, drain terminal coupled to node N2 and source/drain terminal of MP1, and gate terminal coupled to R0_b (where R0_b is inverse of R0 of FIG. 2A). In one embodiment, the static retention scheme of FIG. 4 comprises p-type MP3 with its source terminal coupled to Vcc, drain terminal coupled to node N3, and gate terminal coupled to R1_b (where signal R1_b is inverse of signal R1 of FIG. 2A).

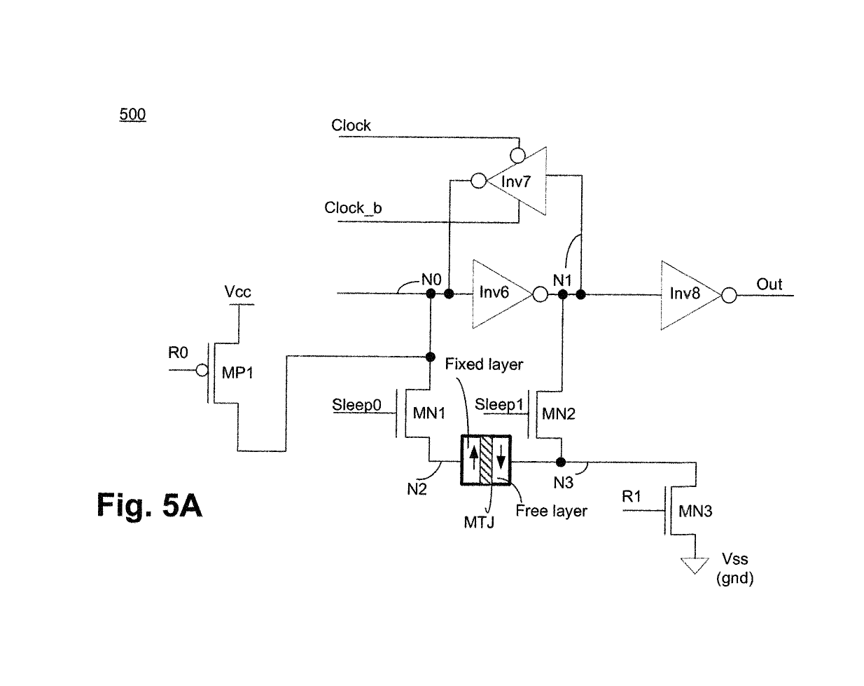

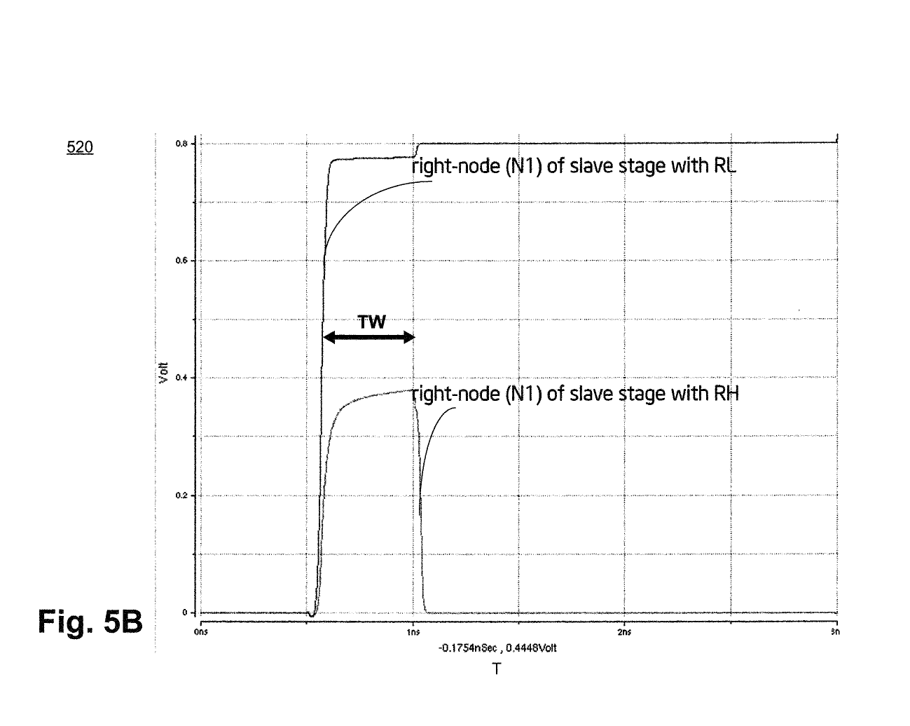

FIG. 5A is a memory cell 500 with retention and using single resistive element and a dynamic restore scheme, according to another embodiment of the disclosure. It is pointed out that those elements of FIG. 5 having the same reference numbers (or names) as the elements of any other figure can operate or function in any manner similar to that described, but are not limited to such.

The storing of data in the single MTJ device is similar to that of embodiment of FIG. 2A. So as not to obscure the embodiment of FIG. 5A, the storing aspect is not repeated. Compared to the static restore scheme of FIG. 2A, the embodiment of memory cell 500 comprises a dynamic restore scheme.

In one embodiment, the dynamic restore scheme of memory cell 500 comprises p-type transistor MP1 with its drain terminal coupled to node N0, source terminal coupled Vcc, and gate terminal controlled by R0. In one embodiment, the dynamic restore scheme of memory cell 500 further comprises n-type transistor MN3 with its source terminal coupled to Vss, drain terminal coupled to node N3, and gate terminal controlled by R1.

In one embodiment, during read/restore operation, Sleep0 and Sleep1 are independently controlled. In one embodiment, in the dynamic restore scheme, node N0 is pre-charged using MP1 and conditionally discharged depending on the resistivity state of the MTJ device (i.e., RH or RL). In one embodiment, during restore, R0 is coupled to Vss to pre-charge node N0. After that R0, R1 and Sleep0 nodes are coupled to Vcc. In one embodiment, Sleep1 is coupled to Vss when Sleep0 is coupled to Vcc.

In one embodiment, depending on the resistivity state of the MTJ device (i.e., RH or RL), node N0 is conditionally discharged. For example, when the resistivity state of the MTJ device is high (i.e., RH), voltage on node N0 does not fall below the threshold of Inv 6. In such an embodiment, node N1 is driven to Vss. When the resistivity state of the MTJ device is low (i.e., RL), voltage on node N0 goes to above threshold of Inv6 and so voltage on node N1 raises to Vcc.

FIG. 5B is a plot 520 showing timing waveforms during the restore operation of dynamic restore scheme of FIG. 5A, according to one embodiment of the disclosure. It is pointed out that those elements of FIG. 5B having the same reference numbers (or names) as the elements of any other figure can operate or function in any manner similar to that described, but are not limited to such.

The x-axis of plot 520 is time and the y-axis is voltage. Plot 520 shows two waveforms, one on the top and one on the bottom. The top waveform is the voltage on node N1 when resistivity of MTJ device is low (i.e., first state of MJT device, also referred to as RL) while the bottom waveform is the voltage on node N1 when resistivity of MTJ device is high (i.e., second state of MTJ device also referred to as RH). Here, TW is the time window during restore operation.

Table 1 shows a comparison of the static restore scheme of FIG. 2A and dynamic restore scheme of FIG. 5A.

TABLE 1
Comparison of static and dynamic restore schemes

| | Static Scheme | Dynamic Scheme |
|---|---|---|
| Read-time | 0.5 ns | 1.1 ns |
| Read-energy | 1 | 2 |
| (normalized) | | |
| TMR Required | 60% | 60% |
| Area | 1 | 1 |
| (normalized) | | |
| RL (Required) | 1 kΩ | 20 kΩ |

Table 1 compares read-time, read-energy (normalized), TMR (tunneling magneto resistance), circuit area (normalized), and required or desired low resistivity of the resistive memory, according to one embodiment. TMR may be expressed as (RH−RL)/RL×100%, where RH and RL are high and low resistances of the resistive device, respectively.

In one embodiment, static restore scheme offers faster read-time (than dynamic restore scheme) which improves exit time from sleep mode. In one embodiment, both static restore scheme and dynamic restore scheme occupy comparable circuit areas. In one embodiment, static restore scheme consumes less power than dynamic restore scheme. In one embodiment, static restore scheme may be more useful than the dynamic restore scheme for cases when resistive memory has a low resistivity, for example, on the order of kilo ohms. In one embodiment, dynamic restore scheme may be more useful than the static restore scheme for cases when resistive memory has a low resistivity, for example, on the order of 10s of kilo ohms.

The embodiments may have several applications. For example, the embodiments may be used as apart of an advanced power management strategy for a processor that allows for fine-grain, fast power gating of logic units while retaining critical state as in the “always on” flip-flops. The embodiments also demonstrate lower voltage operation compared to conventional retention flip-flops of FIG. 1 and thus improving performance and reducing power consumption. The embodiments result in lower average power, translating to longer battery life in mobile applications.

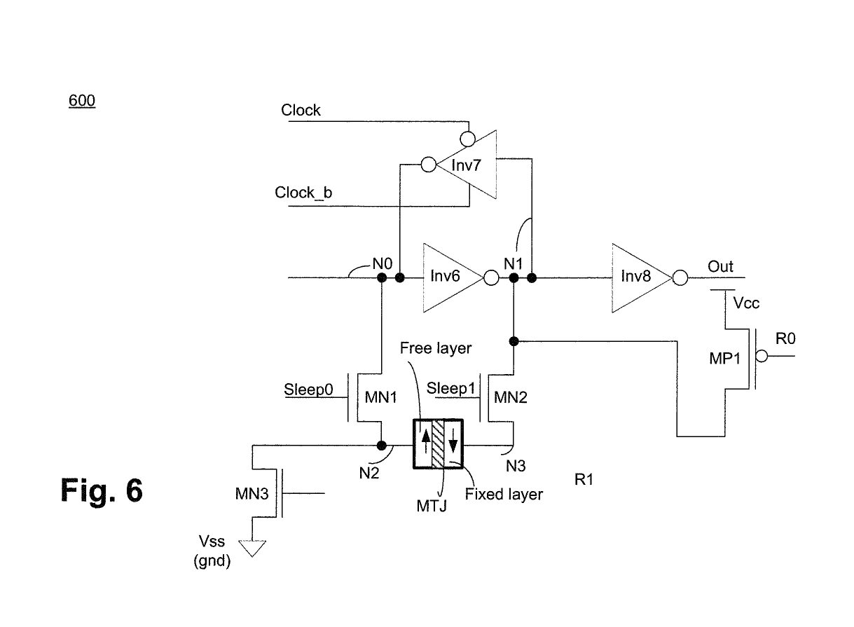

FIG. 6 is a memory cell 600 with retention and using single resistive element and a dynamic restore scheme, according to another embodiment of the disclosure. It is pointed out that those elements of FIG. 6 having the same reference numbers (or names) as the elements of any other figure can operate or function in any manner similar to that described, but are not limited to such.

The embodiment of FIG. 6 is similar to the embodiment of FIG. 5A except that MP1 is now coupled to node N1 and drain/source terminal of MN2 while MN3 is coupled to node N2 and source/drain terminal of MN1. The operation of memory cell 600 is similar to the operation of memory cell 500. In this embodiment, MTJ device is flipped i.e., free layer is now coupled to node N2 and fixed layer is now coupled to node N3.

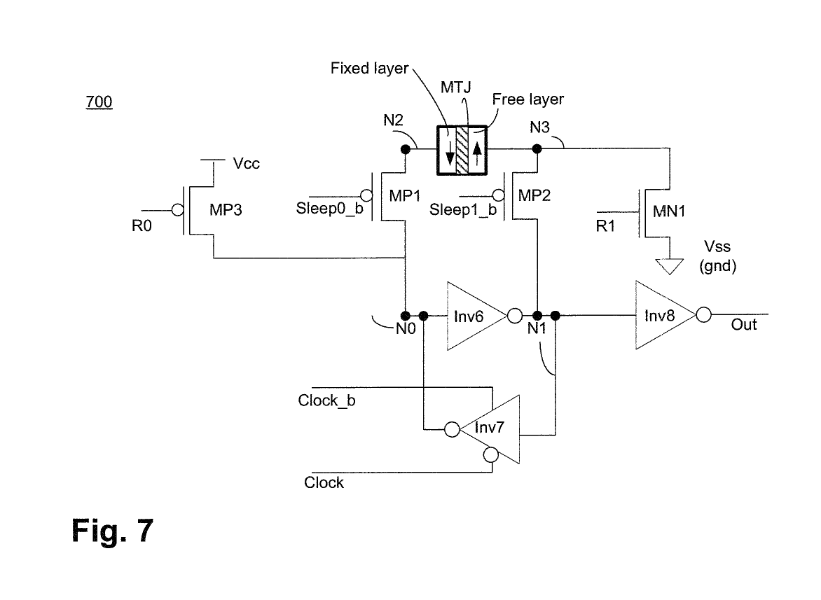

FIG. 7 is a memory cell 700 with retention and using single resistive element and a dynamic restore scheme, according to another embodiment of the disclosure. It is pointed out that those elements of FIG. 7 having the same reference numbers (or names) as the elements of any other figure can operate or function in any manner similar to that described, but are not limited to such.

The embodiment of FIG. 7 is a complementary embodiment of FIG. 5A and functions similarly to FIG. 5A. Memory cell 700 uses p-type sleep transistors MP1 and MP2 instead of n-type sleep transistors MN1 and MN2 of FIG. 5A. In this embodiment, MP1 and MP2 are controlled by signals Sleep0_b and Sleep1_b, where signal Sleep0_b is inverse of signal Sleep0 (of FIG. 5A) and signal Sleep1_b is inverse of signal Sleep1 (of FIG. 5A). In one embodiment, Sleep0_b and Sleep1_b are tied to the same nodes. In one embodiment, the dynamic retention (or restore) scheme of FIG. 7 comprises MN1 with its source terminal coupled to Vss, drain terminal coupled to node N3 and drain/source terminal of MP2, and gate terminal coupled to R1 (where R1 is same as R1 of FIG. 5A). In one embodiment, the dynamic restore scheme of FIG. 7 comprises p-type MP3 with its source terminal coupled to Vcc, drain terminal coupled to node N0, and gate terminal coupled to R0 (where signal R0 is same as signal R0 of FIG. 5A).

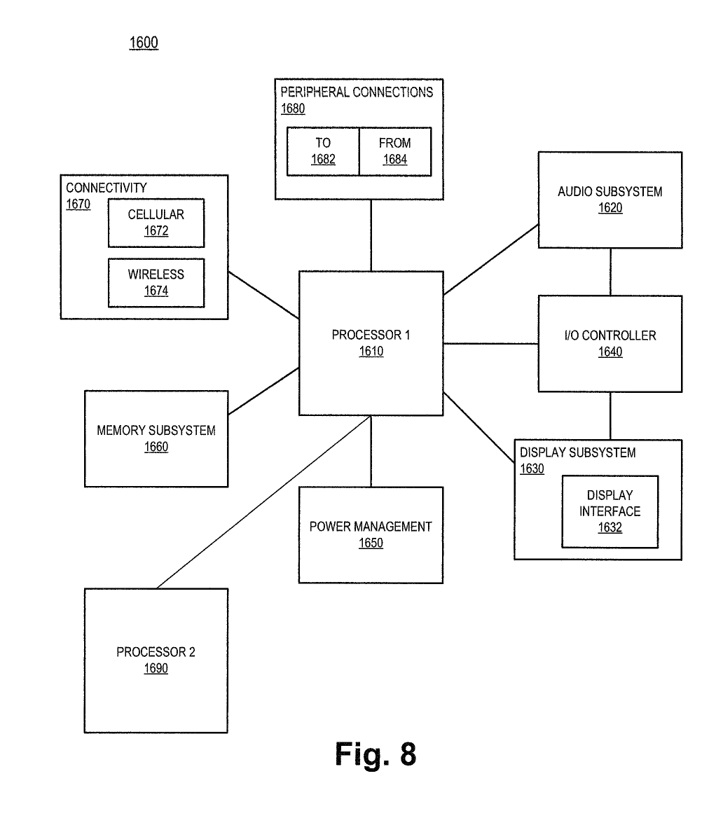

FIG. 8 is a smart device or a computer system or an SoC (system-on-chip) 1600 with the memory cell with retention using single resistive element, according to one embodiment of the disclosure. It is pointed out that those elements of FIG. 8 having the same reference numbers (or names) as the elements of any other figure can operate or function in any manner similar to that described, but are not limited to such.

FIG. 8 illustrates a block diagram of an embodiment of a mobile device in which flat surface interface connectors could be used. In one embodiment, computing device 1600 represents a mobile computing device, such as a computing tablet, a mobile phone or smart-phone, a wireless-enabled e-reader, or other wireless mobile device. It will be understood that certain components are shown generally, and not all components of such a device are shown in computing device 1600.

In one embodiment, computing device 1600 includes a first processor 1610 with the memory cell with retention using resistive memory described with reference to embodiments discussed. Other blocks of the computing device 1600 may also include apparatus of the memory cells with retention using resistive memory described with reference to embodiments. The various embodiments of the present disclosure may also comprise a network interface within 1670 such as a wireless interface so that a system embodiment may be incorporated into a wireless device, for example, cell phone or personal digital assistant or a wearable device.

In one embodiment, processor 1610 (and processor 1690) can include one or more physical devices, such as microprocessors, application processors, microcontrollers, programmable logic devices, or other processing means. Processor 1690 may be optional. While the embodiment shows two processors, a single or more than two processors may be used. The processing operations performed by processor 1610 include the execution of an operating platform or operating system on which applications and/or device functions are executed. The processing operations include operations related to I/O (input/output) with a human user or with other devices, operations related to power management, and/or operations related to connecting the computing device 1600 to another device. The processing operations may also include operations related to audio I/O and/or display I/O.

In one embodiment, computing device 1600 includes audio subsystem 1620, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 1600, or connected to the computing device 1600. In one embodiment, a user interacts with the computing device 1600 by providing audio commands that are received and processed by processor 1610.

Display subsystem 1630 represents hardware (e.g., display devices) and software (e.g., drivers) components that provide a visual and/or tactile display for a user to interact with the computing device 1600. Display subsystem 1630 includes display interface 1632, which includes the particular screen or hardware device used to provide a display to a user. In one embodiment, display interface 1632 includes logic separate from processor 1610 to perform at least some processing related to the display. In one embodiment, display subsystem 1630 includes a touch screen (or touch pad) device that provides both output and input to a user.

I/O controller 1640 represents hardware devices and software components related to interaction with a user. I/O controller 1640 is operable to manage hardware that is part of audio subsystem 1620 and/or display subsystem 1630. Additionally, I/O controller 1640 illustrates a connection point for additional devices that connect to computing device 1600 through which a user might interact with the system. For example, devices that can be attached to the computing device 1600 might include microphone devices, speaker or stereo systems, video systems or other display devices, keyboard or keypad devices, or other I/O devices for use with specific applications such as card readers or other devices.

As mentioned above, I/O controller 1640 can interact with audio subsystem 1620 and/or display subsystem 1630. For example, input through a microphone or other audio device can provide input or commands for one or more applications or functions of the computing device 1600. Additionally, audio output can be provided instead of, or in addition to display output. In another example, if display subsystem 1630 includes a touch screen, the display device also acts as an input device, which can be at least partially managed by I/O controller 1640. There can also be additional buttons or switches on the computing device 1600 to provide I/O functions managed by I/O controller 1640.

In one embodiment, I/O controller 1640 manages devices such as accelerometers, cameras, light sensors or other environmental sensors, or other hardware that can be included in the computing device 1600. The input can be part of direct user interaction, as well as providing environmental input to the system to influence its operations (such as filtering for noise, adjusting displays for brightness detection, applying a flash for a camera, or other features).

In one embodiment, computing device 1600 includes power management 1650 that manages battery power usage, charging of the battery, and features related to power saving operation. Memory subsystem 1660 includes memory devices for storing information in computing device 1600. Memory can include nonvolatile (state does not change if power to the memory device is interrupted) and/or volatile (state is indeterminate if power to the memory device is interrupted) memory devices. Memory subsystem 1660 can store application data, user data, music, photos, documents, or other data, as well as system data (whether long-term or temporary) related to the execution of the applications and functions of the computing device 1600.

Elements of embodiments are also provided as a machine-readable medium (e.g., memory 1660) for storing the computer-executable instructions (e.g., instructions to implement any other processes discussed herein). The machine-readable medium (e.g., memory 1660) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 1670 includes hardware devices (e.g., wireless and/or wired connectors and communication hardware) and software components (e.g., drivers, protocol stacks) to enable the computing device 1600 to communicate with external devices. The computing device 1600 could be separate devices, such as other computing devices, wireless access points or base stations, as well as peripherals such as headsets, printers, or other devices.

Connectivity 1670 can include multiple different types of connectivity. To generalize, the computing device 1600 is illustrated with cellular connectivity 1672 and wireless connectivity 1674. Cellular connectivity 1672 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 1674 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 1680 include hardware interfaces and connectors, as well as software components (e.g., drivers, protocol stacks) to make peripheral connections. It will be understood that the computing device 1600 could both be a peripheral device (“to” 1682) to other computing devices, as well as have peripheral devices (“from” 1684) connected to it. The computing device 1600 commonly has a “docking” connector to connect to other computing devices for purposes such as managing (e.g., downloading and/or uploading, changing, synchronizing) content on computing device 1600. Additionally, a docking connector can allow computing device 1600 to connect to certain peripherals that allow the computing device 1600 to control content output, for example, to audiovisual or other systems.

In addition to a proprietary docking connector or other proprietary connection hardware, the computing device 1600 can make peripheral connections 1680 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. For example, other memory architectures e.g., Dynamic RAM (DRAM) may use the embodiments discussed. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

For example, in one embodiment apparatus comprises: a memory element including cross-coupled cells having a first node and a second node; a first transistor coupled to the first node; a second transistor coupled to the second node; and a resistive memory element coupled to the first and second transistors. In one embodiment, apparatus further comprises a third transistor coupled to the first transistor and the resistive memory, the third transistor operable to turn on for restoring data from the resistive memory element to the first and second nodes. In one embodiment, apparatus further comprises a fourth transistor coupled to the second transistor and the resistive memory, the fourth transistor operable to turn on for restoring data from the resistive memory element to the first and second nodes.

In one embodiment, apparatus further comprises a fifth transistor coupled to the first node, the fifth transistor operable to pre-charge the first node for restoring data, from the resistive memory element, to the first and second nodes. In one embodiment, the first and second transistors are controllable by a low power mode signal. In one embodiment, the resistive memory element is a single resistive memory element.

In one embodiment, the resistive memory element is one of: magnetic tunnel junction (MTJ) device; conductive bridge RAM (CBRAM), or bi-stable organic memories. In one embodiment, the memory element is part of one of: a flip-flop; a latch; or a static random memory. In one embodiment, the cross-coupled cells comprise at least two inverters.

In another example, in one embodiment, a system comprises: a memory unit; a processor, coupled to the memory unit, the processor including an apparatus according to embodiments discussed above; and a wireless interface for allowing the processor to communicate with another device. In one embodiment, the system further comprises a display unit. In one embodiment, the display unit is a touch screen.

In another example, in one embodiment, an apparatus comprises: cross-coupled inverters having a first node and a second node; a first transistor having a source/drain terminal coupled to the first node, and a gate terminal; a second transistor having a source/drain terminal coupled to the second node, and a gate terminal; a resistive memory element coupled to drain/source terminals of the first and second transistors; and a node coupled to the gate terminals of the first and second transistors, the node to carry a signal to cause the first and second transistors to turn on during a low power mode.

In one embodiment, apparatus further comprises a third transistor coupled to the first transistor and the resistive memory, the third transistor operable to turn on for restoring data from the resistive memory element to the first and second nodes. In one embodiment, apparatus further comprises a fourth transistor coupled to the second transistor and the resistive memory, the fourth transistor operable to turn on for restoring data from the resistive memory element to the first and second nodes. In one embodiment, the resistive memory element is a single resistive memory element.

In one embodiment, the resistive memory element is one of: magnetic tunnel junction (MTJ) device; conductive bridge RAM (CBRAM), or bi-stable organic memories etc. In one embodiment, the cross-coupled inverters are part of one of: a flip-flop; a latch; or a static random memory. In one embodiment, apparatus further comprises a fifth transistor coupled to the first node, the fifth transistor operable to pre-charge the first node for restoring data, from the resistive memory element, to the first and second nodes.

In one embodiment, a system comprises: a memory unit; a processor, coupled to the memory unit, the processor including an apparatus according to embodiments discussed above; and a wireless interface for allowing the processor to communicate with another device. In one embodiment, the system further comprises a display unit. In one embodiment, the display unit is a touch screen.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

1. An apparatus comprising:
a memory element including cross-coupled cells having a first node and a second node;
a first transistor coupled to the first node;
a second transistor coupled to the second node; and
a resistive memory element coupled to the first and second transistors.

2. The apparatus of claim 1 further comprises a third transistor coupled to the first transistor and the resistive memory, the third transistor operable to turn on for restoring data from the resistive memory element to the first and second nodes.

3. The apparatus of claim 1 further comprises a fourth transistor coupled to the second transistor and the resistive memory, the fourth transistor operable to turn on for restoring data from the resistive memory element to the first and second nodes.

4. The apparatus of claim 1 further comprises a fifth transistor coupled to the first node, the fifth transistor operable to pre-charge the first node for restoring data, from the resistive memory element, to the first and second nodes.

5. The apparatus of claim 1, wherein the first and second transistors are controllable by a low power mode signal.

6. The apparatus of claim 1, wherein the resistive memory element is a single resistive memory element.

7. The apparatus of claim 1, wherein the resistive memory element is one of:
magnetic tunnel junction (MTJ) device;
conductive bridge RAM (CBRAM), or
bi-stable organic memories.

8. The apparatus of claim 1, wherein the memory element is part of one of:
a flip-flop;
a latch; or
a static random memory.

9. The apparatus of claim 1, wherein the cross-coupled cells comprise at least two inverters.

10. An apparatus comprising:
cross-coupled inverters having a first node and a second node;
a first transistor having a source/drain terminal coupled to the first node, and a gate terminal;
a second transistor having a source/drain terminal coupled to the second node, and a gate terminal;
a resistive memory element coupled to drain/source terminals of the first and second transistors; and
a node coupled to the gate terminals of the first and second transistors, the node to carry a signal to cause the first and second transistors to turn on during a low power mode.

11. The apparatus of claim 10 further comprises a third transistor coupled to the first transistor and the resistive memory, the third transistor operable to turn on for restoring data from the resistive memory element to the first and second nodes.

12. The apparatus of claim 10 further comprises a fourth transistor coupled to the second transistor and the resistive memory, the fourth transistor operable to turn on for restoring data from the resistive memory element to the first and second nodes.

13. The apparatus of claim 10, wherein the resistive memory element is a single resistive memory element.

14. The apparatus of claim 10, wherein the resistive memory element is one of:
magnetic tunnel junction (MTJ) device;
conductive bridge RAM (CBRAM), or
bi-stable organic memories etc.

15. The apparatus of claim 10, wherein the cross-coupled inverters are part of one of:
a flip-flop;
a latch; or
a static random memory.

16. The apparatus of claim 10 further comprises a fifth transistor coupled to the first node, the fifth transistor operable to pre-charge the first node for restoring data, from the resistive memory element, to the first and second nodes.

17. A system comprising:
a memory unit;
a processor, coupled to the memory unit, the processor including an apparatus comprising:
a memory element including cross-coupled cells having a first node and a second node;
a first transistor coupled to the first node;
a second transistor coupled to the second node; and
a resistive memory element coupled to the first and second transistors; and
a wireless interface for allowing the processor to communicate with another device.

18. The system of claim 17 further comprises a display unit.

19. The system of claim 18, wherein the display unit is a touch screen.

20. (canceled)

21. (canceled)

22. (canceled)

23. The system of claim 17, wherein the apparatus further comprises a third transistor coupled to the first transistor and the resistive memory, the third transistor operable to turn on for restoring data from the resistive memory element to the first and second nodes.
